(19) United States
(12) Patent Application Publication
(10) Pub. No.: US 2026/0047447 A1
(43) Pub. Date: Feb. 12, 2026

(54) PACKAGE STRUCTURE AND METHOD OF FORMING THEREOF

(71) Applicant: CHINGIS TECHNOLOGY CORPORATION, Hsinchu City (TW)

(72) Inventor: Cheng-Fu YU, Hsinchu City (TW)

(21) Appl. No.: 18/945,664

(22) Filed: Nov. 13, 2024

(30) Foreign Application Priority Data
Aug. 12, 2024 (TW) 113130204

(51) Int. Cl. H01L 23/495; H01L 21/48; H01L 21/78; H01L 23/00

(52) U.S. Cl. CPC H01L 23/49513; H01L 21/4821; H01L 23/49586; H01L 24/32; H01L 24/83; H01L 24/94; H01L 21/78; H01L 2224/32245; H01L 2224/8302; H01L 2224/83191; H01L 2224/94

(57) ABSTRACT

A method of forming a package structure includes disposing a die adhesive layer on a wafer, lowering a partial connecting property of the die adhesive layer, separating a plurality of dies of the wafer and disposing each of the dies on a leadframe. A connecting property of a partial area of the die adhesive layer is lowered, and the connecting property of the partial area of the die adhesive layer is corresponding to a plurality of cutting streets of the wafer. The dies are separated according to the cutting streets of the wafer. The partial area of the die adhesive layer is corresponding to a plurality of leads of the leadframe, and a connecting strength between the die adhesive layer and each of the leads is lower than a connecting strength between the die adhesive layer and a die pad of the leadframe.

### RELATED APPLICATIONS

This application claims priority to Taiwan Application Serial Number 113130204, filed Aug. 12, 2024, which is herein incorporated by reference.

### BACKGROUND

### Technical Field

The present disclosure relates to a package structure and a method of forming thereof. More particularly, the present disclosure relates to a package structure and a method of forming thereof which can prevent from the crack of the colloid of the product owing to the stress.

### Description of Related Art

In the package structure of the prior art, the stress concentration easily occurs on the colloid of the product contacted with the leads when the area of the die is larger than the area of the die pad. In other words, the stress of the periphery of the die contacted with the leads is higher, and hence the crack of the colloid of the product after 500 times of the thermal cycling test is easily formed. Therefore, a package structure and a method of forming thereof, which can solve the crack problem of the colloid of the product caused by the stress concentration, needs to be developed.

### SUMMARY

According to one aspect of the present disclosure, a method of forming a package structure includes disposing a die adhesive layer on a wafer, lowering a partial connecting property of the die adhesive layer, separating a plurality of dies of the wafer and disposing each of the dies on a leadframe. A connecting property of a partial area of the die adhesive layer is lowered, and the connecting property of the partial area of the die adhesive layer is corresponding to a plurality of cutting streets of the wafer. The dies are separated according to the cutting streets of the wafer. The partial area of the die adhesive layer is corresponding to a plurality of leads of the leadframe, and a connecting strength between the die adhesive layer and each of the leads is lower than a connecting strength between the die adhesive layer and a die pad of the leadframe.

According to one aspect of the present disclosure, a package structure includes a leadframe, a die and a die adhesive layer. The leadframe includes a plurality of leads and a die pad. The die is disposed on the die pad. The die adhesive layer is disposed between the die and the leadframe, wherein a connecting strength between the die adhesive layer and each of the leads is lower than a connecting strength between the die adhesive layer and the die pad.

### BRIEF DESCRIPTION OF THE DRAWINGS

FIG. 1 is a step flow chart of a method of forming a package structure according to the 1st example of the present disclosure.

FIG. 2 is a schematic view of the step according to the 1st example in FIG. 1.

FIG. 3 is a cross-sectional schematic view of a die adhesive layer according to the 1st example in FIG. 2.

FIG. 4 is a schematic view of the step according to the 1st example in FIG. 1.

FIG. 5 is a cross-sectional schematic view of the die adhesive layer and the wafer according to the 1st example in FIG. 4.

FIG. 6 is a schematic view of the step according to the 1st example in FIG. 1.

FIG. 7 is a cross-sectional schematic view of the die adhesive layer and the die according to the 1st example in FIG. 6.

FIG. 8 is a schematic view of the package structure according to the 1st example in FIG. 1.

FIG. 9 is a cross-sectional schematic view of the package structure according to the 1st example in FIG. 8.

FIG. 10 is a step flow chart of a method of forming a package structure according to the 2nd example of the present disclosure.

FIG. 11 is a schematic view of the step according to the 2nd example in FIG. 10.

FIG. 12 is a cross-sectional schematic view of a die adhesive layer and a wafer according to the 2nd example in FIG. 11.

FIG. 13 is a schematic view of the step according to the 2nd example in FIG. 10.

FIG. 14 is a schematic view of the step according to the 2nd example in FIG. 10.

FIG. 15 is a cross-sectional schematic view of the die adhesive layer and a die according to the 2nd example in FIG. 14.

FIG. 16 is a step flow chart of a method of forming a package structure according to the 3rd example of the present disclosure.

FIG. 17 is a schematic view of the steps according to the 3rd example in FIG. 16.

FIG. 18 is a schematic view of the step according to the 3rd example in FIG. 16.

### DETAILED DESCRIPTION

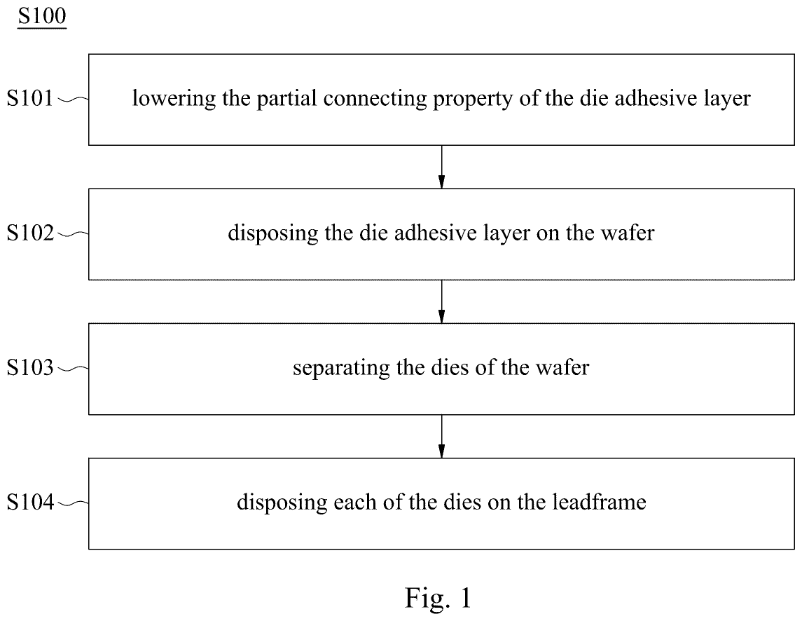

FIG. 1 is a step flow chart of a method of forming a package structure S100 according to the 1st example of the present disclosure. In FIG. 1, the method of forming the package structure S100 includes steps S101, S102, S103, S104.

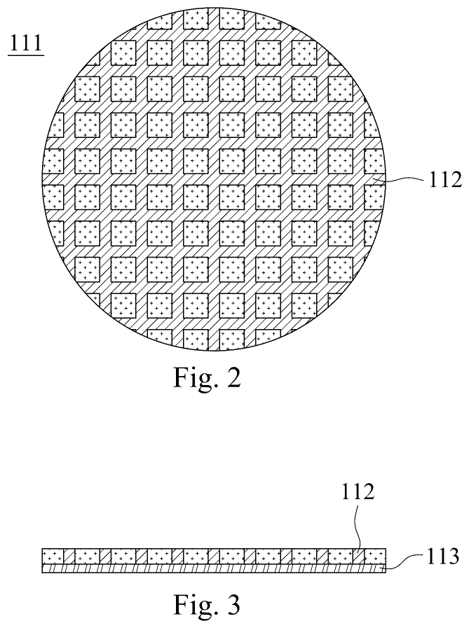

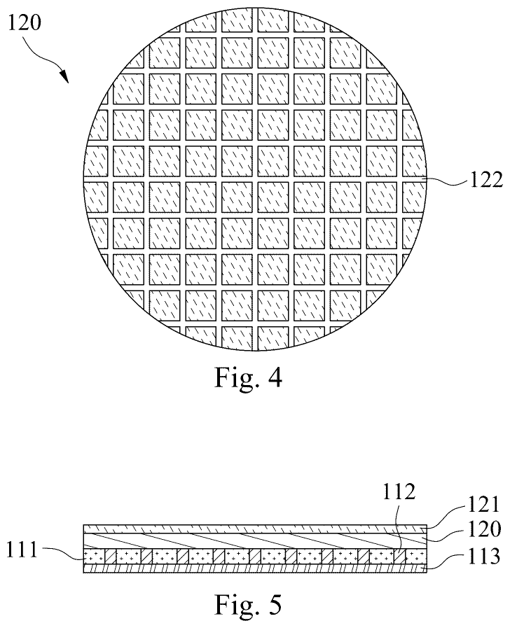

FIG. 2 is a schematic view of the step S101 according to the 1st example in FIG. 1. FIG. 3 is a cross-sectional schematic view of a die adhesive layer 111 according to the 1st example in FIG. 2. In FIGS. 1 to 3, the step S101 includes lowering a partial connecting property of the die adhesive layer 111, wherein a connecting property of a partial area 112 of the die adhesive layer 111 is lowered, the connecting property of the partial area 112 of the die adhesive layer 111 is corresponding to a plurality of cutting streets 122 (labeled in FIG. 4) of a wafer 120 (labeled in FIG. 4), and a base film 113 is disposed on a side of the die adhesive layer 111.

In detail, the connecting property of the partial area 112 of the die adhesive layer 111 can be lowered via a UV light source with a photomask, and a pattern of the photomask is corresponding to the cutting streets 122 of the wafer 120.

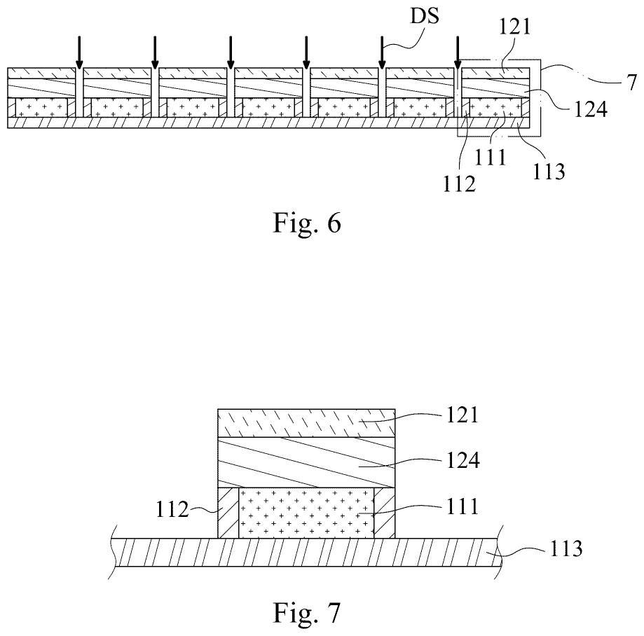

It should be mentioned that lowering the connecting property of the partial area 112 of the die adhesive layer 111 corresponding to the cutting streets 122 of the wafer 120 means that the die adhesive layer 111 of the aforementioned portion does not have the adhesiveness, and a width of a side of a unit area of the partial area 112 of the die adhesive layer 111 can be larger than a width of each of the cutting streets 122 of the wafer 120, wherein the unit area of the partial area 112 is corresponding to an area of one of a plurality of dies 124 (labeled in FIG. 6) of the wafer 120.

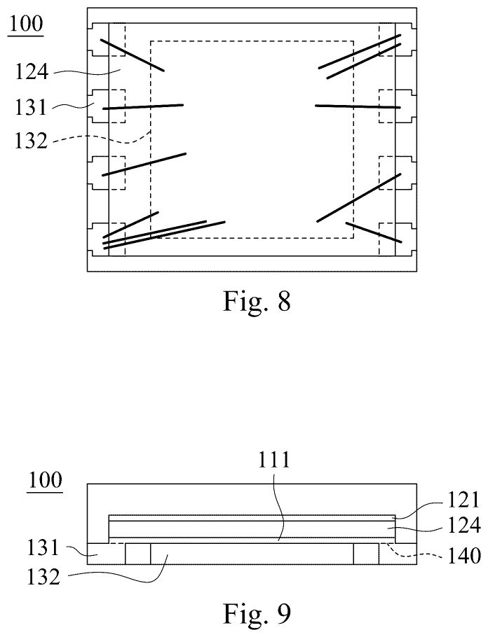

By lowering the connecting property of the die adhesive layer 111 corresponding to positions of the cutting streets 122 of the wafer 120, the method of forming the package structure S100 can be applied to a package structure 100 (labeled in FIG. 8), which an area of the die 124 is larger than an area of a die pad 132 (labeled in FIG. 9) of the leadframe. In particular, the partial area 112 of the die adhesive layer 111 contacted with a plurality of leads 131 (labeled in FIG. 8) of a leadframe (its reference numeral is omitted) has the lower connecting property, so that the buffering function is formed between the partial area 112 of the die adhesive layer 111 and the leads 131. That is, the stress concentration is not easily formed between the partial area 112 of the die adhesive layer 111 and the leads 131, so that the problem of the crack of the colloid of the product after the thermal cycling test owing to the stress concentration can be avoided.

FIG. 4 is a schematic view of the step S102 according to the 1st example in FIG. 1. FIG. 5 is a cross-sectional schematic view of the die adhesive layer 111 and the wafer 120 according to the 1st example in FIG. 4. In FIGS. 1, 4 and 5, the step S102 includes disposing the die adhesive layer 111 on the wafer 120, wherein a front surface of the wafer 120 has a circuit layer 121. In particular, the alignment effect between the wafer 120 and the die adhesive layer 111 can be further enhanced by aligning the cutting streets 122 of the wafer 120 and the partial area 112 of the die adhesive layer 111.

FIG. 6 is a schematic view of the step S103 according to the 1st example in FIG. 1. FIG. 7 is a cross-sectional schematic view of the die adhesive layer 111 and the die 124 according to the 1st example in FIG. 6. In FIGS. 1, 6 and 7, the step S103 includes separating the plurality of dies 124 of the wafer 120, wherein the dies 124 are separated according to the cutting streets 122 of the wafer 120. Moreover, the dies 124 can be separated via a blade or a laser beam along a separating direction DS.

In FIG. 1, the step S104 includes disposing each of the dies 124 on the leadframe, wherein the partial area 112 of the die adhesive layer 111 is corresponding to the leads 131 of the leadframe, and a connecting strength between the die adhesive layer 111 and each of the leads 131 is lower than a connecting strength between the die adhesive layer 111 and the die pad 132 of the leadframe.

FIG. 8 is a schematic view of the package structure 100 according to the 1st example in FIG. 1. FIG. 9 is a cross-sectional schematic view of the package structure 100 according to the 1st example in FIG. 8. In FIGS. 1, 8 and 9, a partial surface of each of the leads 131 of the leadframe can be surface-treated, so that the connecting strength between the partial area 112, which is contacted with each of the leads 131 of the leadframe, of the die adhesive layer 111 and each of the leads 131 of the leadframe. Furthermore, the purpose of the connecting strength between the die adhesive layer 111 and each of the leads 131 lower than the connecting strength between the die adhesive layer 111 and the die pad 132 of the leadframe can be achieved.

In detail, a surface treatment layer 140 is formed on the die adhesive layer 111 which contacts with the partial surface of each of the leads 131, and the surface treatment layer 140 can be made of nickel oxide, copper oxide or polymer, but the present disclosure is not limited thereto. When the area of the die 124 is larger than the area of the die pad 132, the stress between the die 124 and the leads 131 formed owing to the contact can be lowered via the surface treatment layer 140, and a portion of the die adhesive layer 111 contact with the leads 131 can be a buffer layer, so that the problem of the crack of the colloid of the product after the thermal cycling test owing to the stress concentration can be avoided.

It should be mentioned that the leads 131 in FIG. 8 are located on two sides of the die pad 132, a side length of two relative sides of the die 124 is larger than a side length of two relative sides of the die pad 132, and both of two relative sides of the die 124 are disposed on the leads 131, and hence the partial area 112 of the die adhesive layer 111 is located on two sides of the die adhesive layer 111. If the leads of the package structure are located on four sides of the die pad, both of a side length of two relative sides of the die and a side length of another two relative sides of the die are larger than both of a side length of two relative sides of the die pad and a side length of another two relative sides of the die pad, all of two relative sides and another two relative sides of the die are disposed on the leads, and hence the partial area of the die adhesive layer is located on four sides of the die adhesive layer.

In FIG. 9, the package structure 100 includes the leadframe, the die 124 and the die adhesive layer 111, wherein the leadframe includes the leads 131 and the die pad 132, the die 124 is disposed on the die pad 132, and the die adhesive layer 111 is disposed between a back surface of the die 124 and the leadframe. Moreover, the connecting strength between the die adhesive layer 111 and each of the leads 131 is lower than the connecting strength between the die adhesive layer 111 and the die pad 132.

In FIGS. 8 and 9, the area of the die 124 is larger than the area of the die pad 132, the die adhesive layer 111 can be a die attach film (DAF) or a film over wire (FOW), wherein a thickness of the die adhesive layer 111 can be between 10 μm and 100 μm. Further, the thickness of the die adhesive layer 111 can be between 20 μm and 60 μm, but the present disclosure is not limited thereto.

In FIG. 9, the die adhesive layer 111 is contact with the partial surface of each of the leads 131, and the partial surface of each of the leads 131 can includes the surface treatment layer 140, wherein the dotted line in FIG. 9 is configured to indicate the range of the surface treatment layer 140.

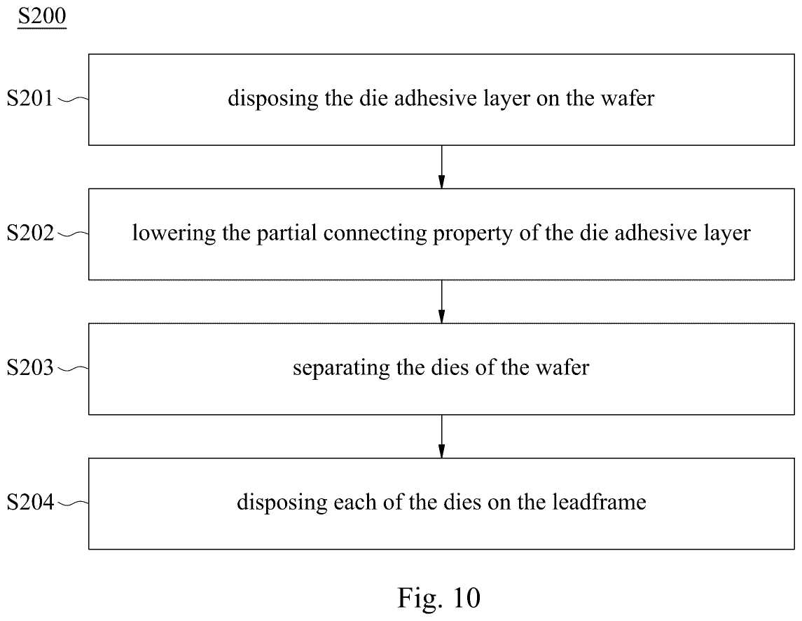

FIG. 10 is a step flow chart of a method of forming a package structure S200 according to the 2nd example of the present disclosure. In FIG. 10, the method of forming the package structure S200 includes steps S201, S202, S203, S204.

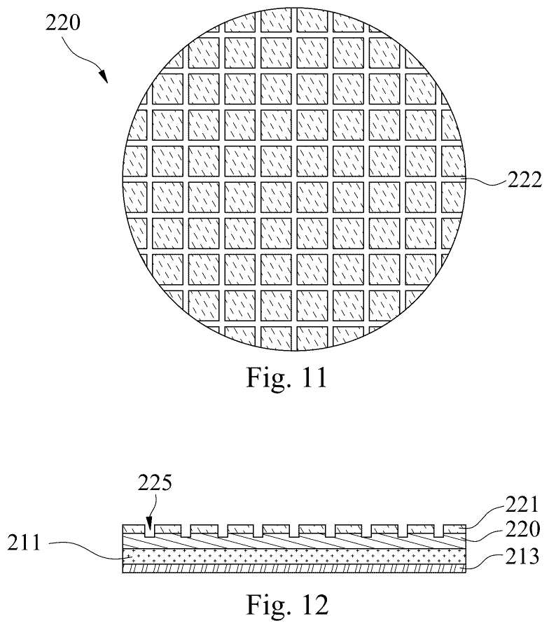

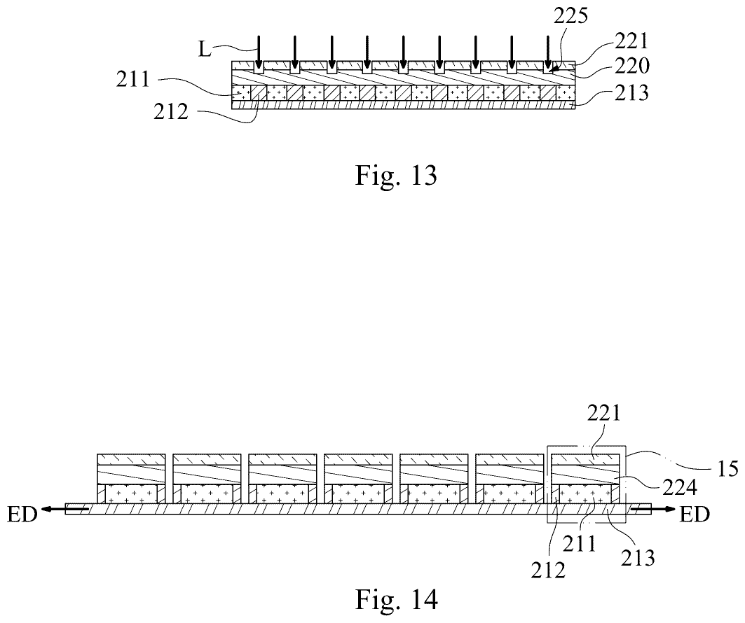

FIG. 11 is a schematic view of the step S201 according to the 2nd example in FIG. 10. FIG. 12 is a cross-sectional schematic view of a die adhesive layer 211 and a wafer 220 according to the 2nd example in FIG. 11. FIG. 13 is a schematic view of the step S202 according to the 2nd example in FIG. 10. In FIGS. 10 to 13, the step S201 includes disposing the die adhesive layer 211 on the wafer 220, and the step S202 includes lowering a partial connecting property of the die adhesive layer 211, wherein a front surface of the wafer 220 has a circuit layer 221, a connecting property of a partial area 212 of the die adhesive layer 211 is lowered, and the connecting property of the partial area 212 of the die adhesive layer 211 is corresponding to a plurality of cutting streets 222 of the wafer 220.

In FIG. 12, before lowering the connecting property of the partial area 212 of the die adhesive layer 211 corresponding to the cutting streets 222 of the wafer 220, the circuit layer 221 of the wafer 220 and the partial surface of the wafer 220 can be removed to form a plurality of recesses 225, wherein the aforementioned portion can be removed via a blade or a laser beam to form the recesses 225, the recesses 225 are corresponding to the cutting streets 222 of the wafer 220, and a width of each of the recesses 225 is less than a width of the partial area 212 of the die adhesive layer 211 in FIG. 13.

In detail, the connecting property of the partial area 212 of the die adhesive layer 211 can be lowered via a stealth laser beam L, wherein a transmission wavelength of the stealth laser beam L should be larger than 1 μm, an energy of the stealth laser beam L can be between 4.5 μJ and 5 μJ, and a depth of the stealth laser beam L can be larger than or equal to 60 μm. Further, an operating temperature of the stealth laser beam L can be larger than 200 degrees Celsius so as to lower the partial connecting property of the die adhesive layer 211, a depth of the heat affected zone of the stealth laser beam L is only between 1 μm and 5 μm, and a thickness of the die adhesive layer 211 is between 20 μm and 60 μm. Therefore, a structure of a base film 213 is not influenced by the heat affected zone thereof, and a width of the heat affected zone of the stealth laser beam L is between 1 μm and 10 μm, wherein the base film 213 is disposed on a side of the die adhesive layer 211, and the die adhesive layer 211 is disposed between the base film 213 and the wafer 220. It should be mentioned that the wafer 220 can be a silicon wafer, the transmission wavelength of the stealth laser beam L is corresponding to a wavelength of the laser beam which can penetrate through the silicon wafer, wherein the wavelength of the laser beam which can penetrate through the silicon wafer is 1064 nm.

Moreover, the recesses 225 are favorable for the alignment during lowering the connecting property of the partial area 212 of the die adhesive layer 211 via the stealth laser beam L, and the connecting property of the partial area 212 of the die adhesive layer 211 corresponding to the circuit layer 221 of the wafer 220 can be further more accurately lowered.

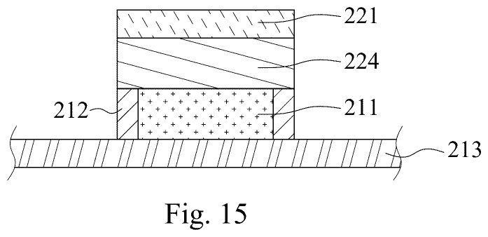

FIG. 14 is a schematic view of the step S203 according to the 2nd example in FIG. 10. FIG. 15 is a cross-sectional schematic view of the die adhesive layer 211 and a die 224 according to the 2nd example in FIG. 14. In FIGS. 10, 14 and 15, the step S203 includes separating the plurality of dies 224 of the wafer 220, wherein the dies 224 are separated according to the cutting streets 222 of the wafer 220.

When the connecting property of the partial area 212 of the die adhesive layer 211 is lowered via the stealth laser beam L, the stealth laser beam L can penetrate through via the base film 213 so as to avoid the hot source concentrating on the wafer 220. Therefore, the connecting property of the partial area 212 of the die adhesive layer 211 can be effectively lowered. In particular, the connecting property of the partial area 212 of the die adhesive layer 211 is lowered via the stealth laser beam L during the step S202, a modified layer can be simultaneously and further formed in an inner portion of the wafer 220 corresponding to the cutting streets 222, and the dies 224 of the wafer 220 can be separated by expanding the base film 213 along an expanding direction ED.

Then, the step S204 includes disposing each of the dies 224 on a leadframe (not shown), wherein the partial area 212 of the die adhesive layer 211 is corresponding to a plurality of leads (not shown) of the leadframe, and a connecting strength between the die adhesive layer 211 and each of the leads is lower than a connecting strength between the die adhesive layer 211 and a die pad (not shown) of the leadframe.

Further, all of other structures and dispositions according to the 2nd example are the same as the structures and the dispositions according to the 1st example, and will not be described again herein.

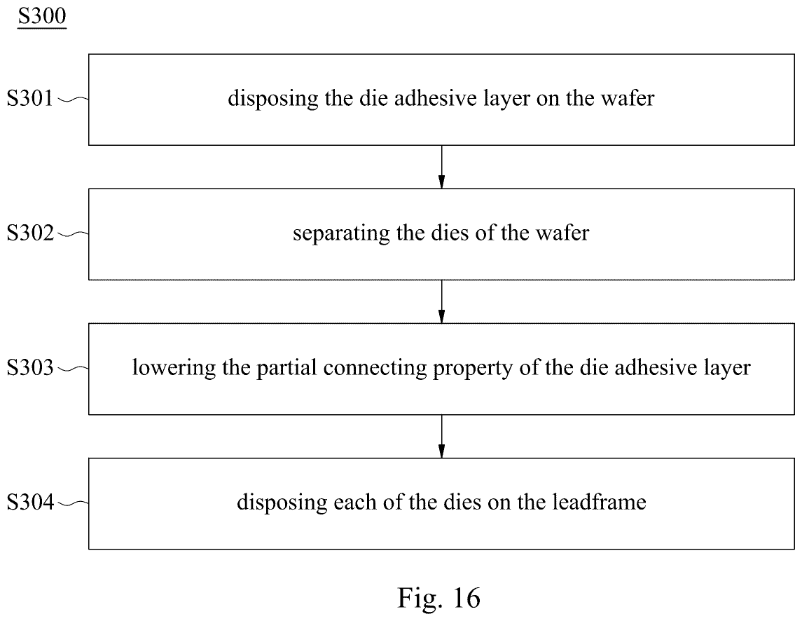

FIG. 16 is a step flow chart of a method of forming a package structure S300 according to the 3rd example of the present disclosure. In FIG. 16, the method of forming the package structure S300 includes steps S301, S302, S303, S304.

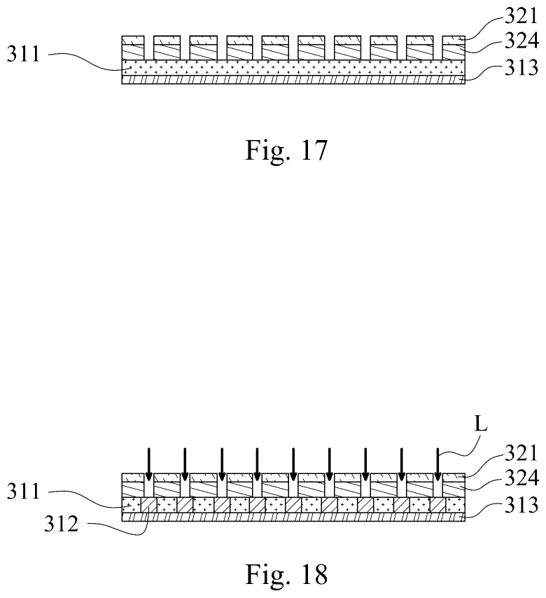

FIG. 17 is a schematic view of the steps S301, S302 according to the 3rd example in FIG. 16. In FIGS. 16 and 17, the step S301 includes disposing a die adhesive layer 311 on a wafer (not shown), and the step S302 includes separating a plurality of dies 324 of the wafer, wherein the dies 324 are separated according to a plurality of cutting streets (not shown) of the wafer, and a front surface of the wafer has a circuit layer 321.

FIG. 18 is a schematic view of the step S303 according to the 3rd example in FIG. 16. In FIGS. 16 and 18, the step S303 includes lowering a partial connecting property of the die adhesive layer 311, wherein a connecting property of a partial area 312 of the die adhesive layer 311 can be lowered via a stealth laser beam L, the connecting property of the partial area 312 of the die adhesive layer 311 is corresponding to the cutting streets of the wafer, and a base film 313 is disposed on a side of the die adhesive layer 311. Moreover, a width of the partial area 312 of the die adhesive layer 311 is wider than a width between adjacent two of the dies 324.

Then, the step S304 includes disposing each of the dies 324 on a leadframe (not shown), wherein the partial area 312 of the die adhesive layer 311 is corresponding to a plurality of leads (not shown) of the leadframe, and a connecting strength between the die adhesive layer 311 and each of the leads is lower than a connecting strength between the die adhesive layer 311 and a die pad (not shown) of the leadframe. It should be mentioned that the partial area 312 of the die adhesive layer 311 between each adjacent two of the dies 324 can be separated via a blade or a laser beam before the step S304.

In particular, the difference between the 3rd example and the 2nd example is the timing of separating the dies of the wafer, and the dies of the wafer are separated before lowering the partial connecting property of the die adhesive layer according to the 3rd example. Therefore, the following alignment of the stealth laser beam can be enhanced by first separating the dies of the wafer, and the connecting property of the partial area of the die adhesive layer corresponding to the circuit layer of the wafer can be further more accurately lowered.

Further, all of other structures and dispositions according to the 3rd example are the same as the structures and the dispositions according to the 2nd example, and will not be described again herein.

In summary, the package structure and the method of forming thereof according to the present disclosure are favorable for preventing from the problem of the excessive stress between the die adhesive layer and the leads, and the die adhesive layer can be further used as the buffer layer so as to protect the periphery of each of the dies, so that the problem of the crack of the colloid of the product after the thermal cycling test owing to the stress concentration can be avoided. Further, there is no necessary to additionally dispose of the buffer layer such as the spacer layer to conquer the aforementioned problem, so that the manufacturing cost can be reduced.

The foregoing description, for purpose of explanation, has been described with reference to specific examples. It is to be noted that Tables show different data of the different examples; however, the data of the different examples are obtained from experiments. The examples were chosen and described in order to best explain the principles of the disclosure and its practical applications, to thereby enable others skilled in the art to best utilize the disclosure and various examples with various modifications as are suited to the particular use contemplated. The examples depicted above and the appended drawings are exemplary and are not intended to be exhaustive or to limit the scope of the present disclosure to the precise forms disclosed. Many modifications and variations are possible in view of the above teachings.

What is claimed is:

1. A method of forming a package structure, comprising:
disposing a die adhesive layer on a wafer;
lowering a partial connecting property of the die adhesive layer, wherein a connecting property of a partial area of the die adhesive layer is lowered, and the connecting property of the partial area of the die adhesive layer is corresponding to a plurality of cutting streets of the wafer;
separating a plurality of dies of the wafer, wherein the dies are separated according to the cutting streets of the wafer; and
disposing each of the dies on a leadframe, wherein the partial area of the die adhesive layer is corresponding to a plurality of leads of the leadframe, and a connecting strength between the die adhesive layer and each of the leads is lower than a connecting strength between the die adhesive layer and a die pad of the leadframe.

2. The method of forming the package structure of claim 1, wherein the connecting property of the partial area of the die adhesive layer is lowered via a stealth laser beam.

3. The method of forming the package structure of claim 2, wherein an energy of the stealth laser beam is between 4.5 μJ and 5 μJ.

4. The method of forming the package structure of claim 2, wherein a depth of the stealth laser beam is larger than or equal to 60 μm.

5. The method of forming the package structure of claim 1, wherein a partial surface of each of the leads of the leadframe is surface-treated.

6. The method of forming the package structure of claim 5, wherein a surface treatment layer is formed on the die adhesive layer which contacts with the partial surface of each of the leads.

7. The method of forming the package structure of claim 6, wherein the surface treatment layer is made of nickel oxide, copper oxide or polymer.

8. The method of forming the package structure of claim 1, wherein the dies are separated via a blade or a laser beam.

9. The method of forming the package structure of claim 1, wherein the connecting property of the partial area of the die adhesive layer is lowered via a UV light source with a photomask.

10. The method of forming the package structure of claim 9, wherein a pattern of the photomask is corresponding to the cutting streets of the wafer.

11. The method of forming the package structure of claim 1, wherein a width of a side of a unit area of the partial area of the die adhesive layer is larger than a width of each of the cutting streets of the wafer.

12. The method of forming the package structure of claim 1, wherein before lowering the connecting property of the partial area of the die adhesive layer corresponding to the cutting streets of the wafer, a circuit layer of the wafer and a partial surface of the wafer are removed to form a plurality of recesses.

13. The method of forming the package structure of claim 12, wherein a width of each of the recesses is less than a width of the partial area of the die adhesive layer.

14. A package structure, comprising:
a leadframe comprising a plurality of leads and a die pad;
a die disposed on the die pad; and
a die adhesive layer disposed between the die and the leadframe, wherein a connecting strength between the die adhesive layer and each of the leads is lower than a connecting strength between the die adhesive layer and the die pad.

15. The package structure of claim 14, wherein the die adhesive layer is contacted with a partial surface of each of the leads, and the partial surface of the each of the leads comprises a surface treatment layer.

16. The package structure of claim 15, wherein the surface treatment layer is made of nickel oxide, copper oxide or polymer.

17. The package structure of claim 14, wherein the die adhesive layer is a die attach film or a film over wire.

18. The package structure of claim 14, wherein a thickness of the die adhesive layer is between 10 μm and 100 μm.

19. The package structure of claim 18, wherein the thickness of the die adhesive layer is between 20 μm and 60 μm.
